(19) United States
(12) Patent Application Publication
(10) Pub. No.: US 2024/0321982 A1
(43) Pub. Date: Sep. 26, 2024

(54) MIDDLE OF LINE CONTACT FOR ADVANCED NODES

(71) Applicant: INTERNATIONAL BUSINESS MACHINES CORPORATION, ARMONK, NY (US)

(72) Inventors: Ruilong Xie, Niskayuna, NY (US); Julien Frougier, Albany, NY (US); Nicolas Jean Loubet, GUILDERLAND, NY (US); Dechao Guo, Niskayuna, NY (US); Ravikumar Ramachandran, Pleasantville, NY (US)

(21) Appl. No.: 18/189,245

(22) Filed: Mar. 24, 2023

(51) Int. Cl. H01L 29/417; H01L 23/522

(52) U.S. Cl. CPC H01L 29/41775; H01L 23/5226

(57) ABSTRACT

A transistor structure including a gate with a dielectric gate cap, a self-aligned source drain contact, where a topmost surface of the self-aligned source drain contact is substantially flush with a topmost surface of a first dielectric layer, a gate contact extending through the first dielectric layer, where a topmost surface of the gate contact is substantially flush with a topmost surface of a second dielectric layer, and a spacer surrounding the gate contact and physically separating it from the self-aligned source drain contact.

### BACKGROUND

The present invention generally relates to semiconductor structures, and more particularly to middle-of-line contacts for advances nodes.

Integrated circuit (IC) chips are formed on semiconductor wafers at increasingly smaller scale. In current technology nodes, such as 7, 10 and 14 nanometer technologies, transistor devices are constructed as three-dimensional (3D) fin field effect transistor (FINFET) structures. However, chipmakers face a myriad of challenges at 5 nm, 3 nm and beyond. Currently, traditional chip scaling continues to slow as process complexities and costs escalate at each node.

### SUMMARY

According to an embodiment of the present invention, a semiconductor structure is provided. The semiconductor structure may include a gate with a dielectric gate cap, a self-aligned source drain contact, where a topmost surface of the self-aligned source drain contact is substantially flush with a topmost surface of a first dielectric layer, a gate contact extending through the first dielectric layer, where a topmost surface of the gate contact is substantially flush with a topmost surface of a second dielectric layer, and a spacer surrounding the gate contact and physically separating it from the self-aligned source drain contact.

According to another embodiment of the present invention, a semiconductor structure is provided. The semiconductor structure may include a gate with a dielectric gate cap, a self-aligned source drain contact, where a topmost surface of the self-aligned source drain contact is substantially flush with a topmost surface of a first dielectric layer, a gate contact extending through the first dielectric layer, where a topmost surface of the gate contact is substantially flush with a topmost surface of a second dielectric layer, a spacer surrounding the gate contact and physically separating it from the self-aligned source drain contact, and gate spacers physically separating the gate from source drain regions, where the spacers directly contact the dielectric gate cap and the spacer.

According to another embodiment of the present invention, a semiconductor structure is provided. The semiconductor structure may include a gate with a dielectric gate cap, a first dielectric layer, a self-aligned source drain contact extending through the first dielectric layer, a second dielectric layer above the first dielectric layer, a gate contact extending through both the first dielectric layer the second dielectric layer, and a sidewall spacer surrounding the gate contact and physically separating it from the self-aligned source drain contact.

### BRIEF DESCRIPTION OF THE DRAWINGS

The following detailed description, given by way of example and not intended to limit the invention solely thereto, will best be appreciated in conjunction with the accompanying drawings, in which:

FIGS. 1, 2, and 3 are cross-sectional views of a semiconductor structure during an intermediate step of a method of fabricating an interconnect structure according to an exemplary embodiment;

FIGS. 4, 5, and 6 are cross-sectional views of the semiconductor after recessing the gates and forming self-aligned gate caps according to an exemplary embodiment;

FIGS. 7, 8, and 9 are cross-sectional views of the semiconductor after forming a first middle-of-line dielectric layer according to an exemplary embodiment;

FIGS. 10, 11, and 12 are cross-sectional views of the semiconductor after forming source drain contact masks and forming source drain contact trenches according to an exemplary embodiment;

FIGS. 13, 14, and 15 are cross-sectional views of the semiconductor after removing the source drain contact masks and forming self-aligned source drain contacts according to an exemplary embodiment;

FIGS. 16, 17, and 18 are cross-sectional views of the semiconductor after forming a second middle-of-line dielectric layer according to an exemplary embodiment;

FIGS. 19, 20, and 21 are cross-sectional views of the semiconductor after forming gate contact masks and forming gate contact trenches according to an exemplary embodiment;

FIGS. 22, 23, and 24 are cross-sectional views of the semiconductor after removing the gate contact masks and forming spacers according to an exemplary embodiment;

FIGS. 25, 26, and 27 are cross-sectional views of the semiconductor after forming via masks and forming via trenches according to an exemplary embodiment;

FIGS. 28, 29, and 30 are cross-sectional views of the semiconductor after forming gate contacts and vias according to an exemplary embodiment; and

FIGS. 31, 32, and 33 are cross-sectional views of the semiconductor after forming a back-end-of-line metallization level including metal lines and back-end-of-line dielectric layer according to an exemplary embodiment.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

Additionally, XYZ Cartesian coordinates may be also shown in each of the drawings to provide additional spatial context. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

As technology nodes continue to decrease beyond 3 nm, forming device contacts has become increasingly difficult. More specifically, additional efforts are required to prevent shorting between the source drain regions and the gate. Self-aligned contacts provide one solution; however, a relatively thick dielectric gate cap is typically used to enable the formation of self-aligned source/drain contacts, and the presence of the relatively thick dielectric gate cap requires a much deeper gate contact (CB) etch process to form the gate contact (CB). The deeper etch further increases any risk of shorting between the gate contact (CB) and the source drain contact (CA), especially if the gate contact overlaps, or is positioned over active regions (CBoA), such as the source drain regions

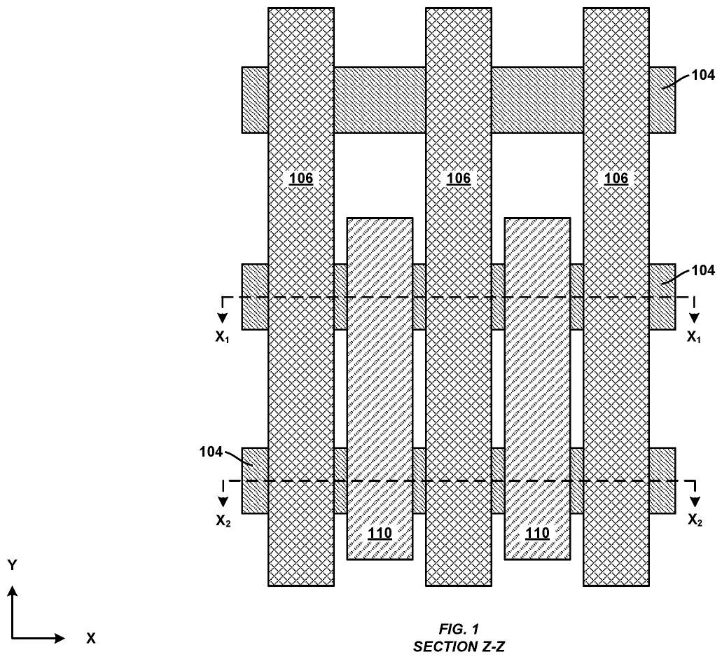

The present invention generally relates to semiconductor structures, and more particularly to middle-of-line contacts for advances nodes. More specifically, the transistor structures and associated method disclosed herein enable a novel solution for providing self-aligned device contacts to prevent shorting between the source drain contacts (CB) and the gate contacts (CA). Exemplary embodiments of transistors having self-aligned device are described in detail below by referring to the accompanying drawings in FIGS. 1 to 33. Those skilled in the art will readily appreciate that the detailed description given herein with respect to these figures is for explanatory purposes as the invention extends beyond these limited embodiments.

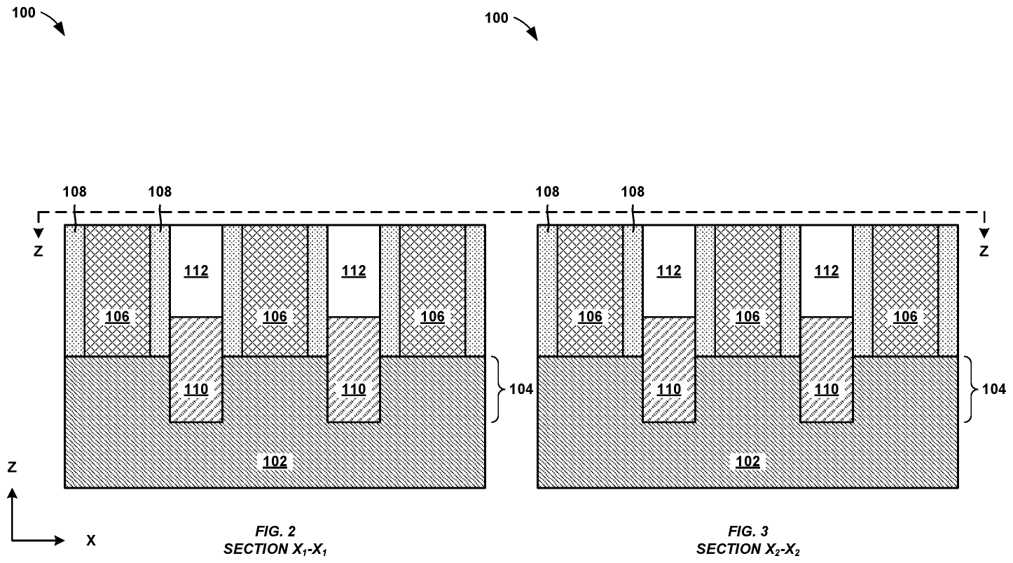

Referring now to FIGS. 1, 2, and 3, a structure 100 is shown during an intermediate step of a method of fabricating a stacked transistor structure according to an embodiment of the invention. FIG. 1 is a representative illustration of a cross-sectional view of the structure 100 shown in FIGS. 2 and 3 taken along line Z-Z and omitting some materials and layers, for example, patterning layers, masking layers and interlevel dielectrics. As such, only pertinent conductive layers and components are shown to provide a clear understanding of their relative orientation. FIG. 2 depicts a cross-sectional view of the structure 100 shown in FIG. 1 taken along line X₁-X₁. FIG. 3 depicts a cross-sectional view of the structure 100 shown in FIG. 1 taken along line X₂-X₂.

The structure 100 illustrated in FIGS. 1-3 includes an array of fin transistors formed in or on a substrate 102 in accordance with known techniques. As illustrated, the structure 100 includes fins 104, gates 106, gate spacers 108, source drain regions 110, and fill dielectric 112. The structure 100 illustrated in FIGS. 1-3 represents a typical array of transistors during fabrication after replacement metal gate operations.

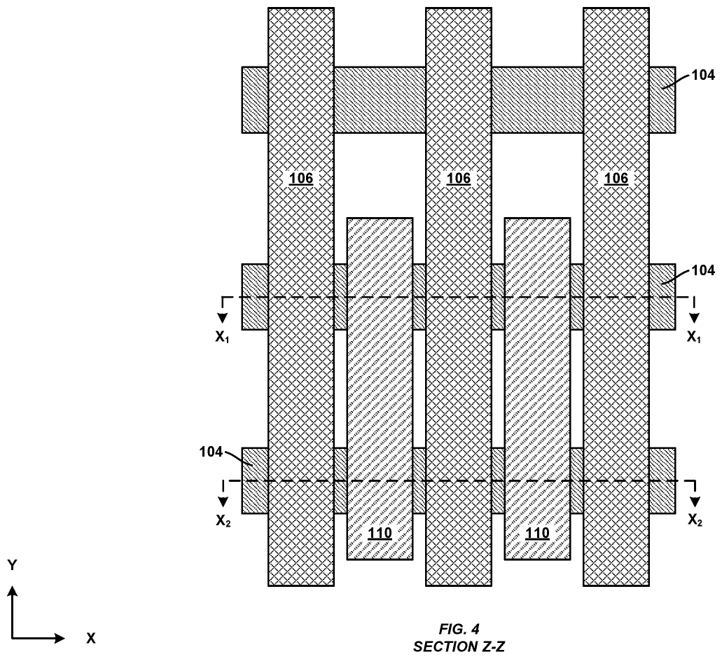

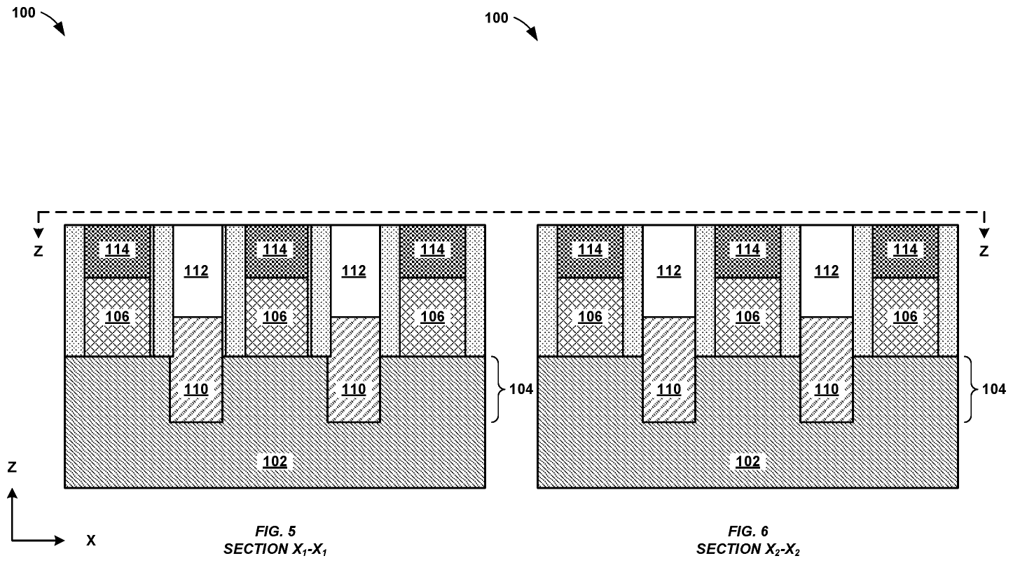

Referring now to FIGS. 4, 5, and 6, a structure 100 is shown after recessing the gates 106 and forming self-aligned gate caps 114 (hereinafter gate caps 114) according to an embodiment of the invention. FIG. 4 is a representative illustration of a cross-sectional view of the structure 100 shown in FIGS. 5 and 6 taken along line Z-Z and omitting some materials and layers, for example, patterning layers, masking layers and interlevel dielectrics. As such, only pertinent conductive layers and components are shown to provide a clear understanding of their relative orientation. FIG. 5 depicts a cross-sectional view of the structure 100 shown in FIG. 4 taken along line X₁-X₁. FIG. 6 depicts a cross-sectional view of the structure 100 shown in FIG. 4 taken along line X₂-X₂.

First, the gates 106 are recessed according to known techniques. Specifically, for example, one or more suitable etching techniques such as dry etch, wet etch, or combination of both may be used to recess the gates 106. In all cases, the chosen etching technique shall be selective to underlying structures, such as for example, the gate spacers 108 and the fill dielectric 112, as illustrated.

Next, the gate caps 114 of the present embodiment are formed directly on the recessed gates 106, and more specifically fill the voids created by recessing the gates 106 as illustrated and according to known techniques. Specifically, a blanket dielectric layer is deposited across the structure 100 followed by a chemical mechanical polishing technique to remove excess unwanted dielectric material from upper surfaces of the structure 100. As a result, topmost surfaces of the gate caps 114 will be flush, or substantially flush, with topmost surfaces of the gate spacers 108 and the fill dielectric 112.

The gate spacers 108 and the gate caps 114 are provided to separate and electrically insulate the gates 106 from subsequently formed structures, such as, for example, contact structures. The gate spacers 108 are critical for electrically insulating the gates 106 from any subsequently formed source drain regions or contact structures, as described below. The gate caps 114 may further protect the gates 106 during subsequent processing. In at least one embodiment, the gate spacers 108 and the gate caps 114 include silicon nitride, silicon boron nitride, silicon carbon nitride, silicon boron carbon nitride, or other known equivalents.

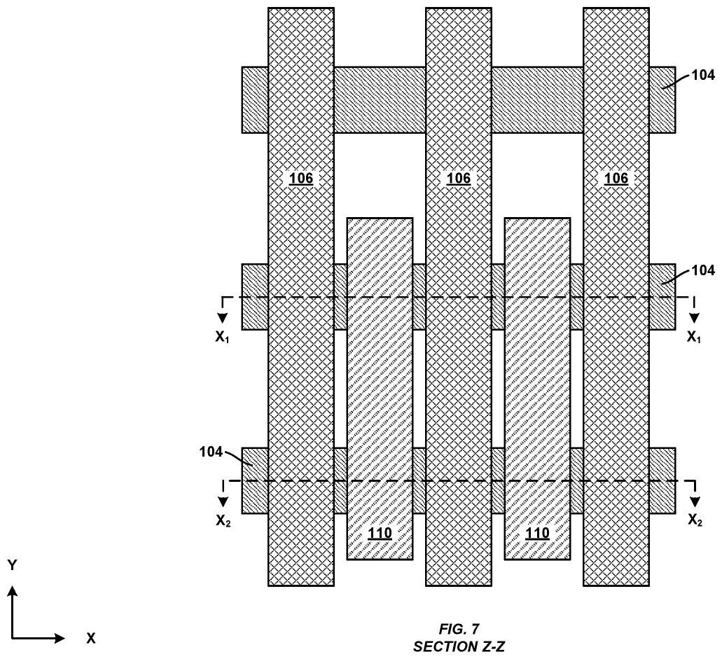

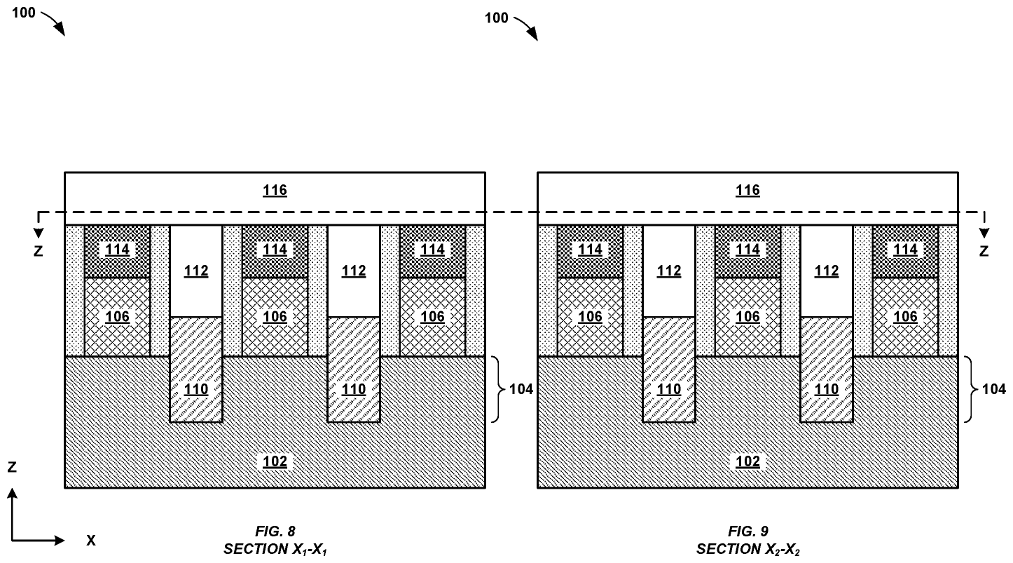

Referring now to FIGS. 7, 8, and 9, a structure 100 is shown after forming a first middle-of-line dielectric layer 116 (hereinafter first MOL dielectric 116) according to an embodiment of the invention. FIG. 7 is a representative illustration of a cross-sectional view of the structure 100 shown in FIGS. 8 and 9 taken along line Z-Z and omitting some materials and layers, for example, patterning layers, masking layers and interlevel dielectrics. As such, only pertinent conductive layers and components are shown to provide a clear understanding of their relative orientation. FIG. 8 depicts a cross-sectional view of the structure 100 shown in FIG. 7 taken along line X₁-X₁. FIG. 9 depicts a cross-sectional view of the structure 100 shown in FIG. 7 taken along line X₂-X₂.

The first MOL dielectric 116 of the present embodiment is blanket deposited across the structure 100 as illustrated and according to known techniques.

The first MOL dielectric 116 may include any suitable dielectric material, for example, oxide, nitride, silicon oxide (SiO₂), silicon nitride (Si₃N₄), hydrogenated silicon carbon oxide (SiCOH), carbon rich silicon carbon nitride (SiCN), silicon based low-K dielectrics, porous dielectrics, or some combination thereof. The term “low-κ” as used herein refers to a material having a relative dielectric constant k which is lower than that of silicon dioxide. In an embodiment, the first MOL dielectric 116 can be formed using a deposition technique including, for example, chemical vapor deposition (CVD), plasma enhanced chemical vapor deposition (PECVD), physical vapor deposition (PVD), atomic layer deposition (ALD), evaporation, spin-on coating, or sputtering. For example, in an embodiment, the first MOL dielectric 116 is made from hydrogenated silicon carbon oxide (SiCOH). According to at least one embodiment, the first MOL dielectric 116 is made from an identical dielectric material as the fill dielectric 112. In at least another embodiment, the first MOL dielectric 116 is made from a different material than the fill dielectric 112.

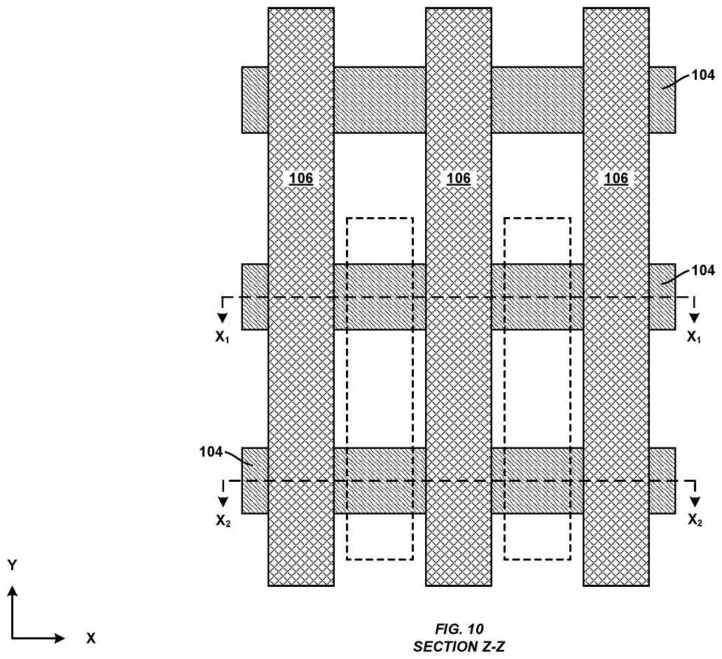

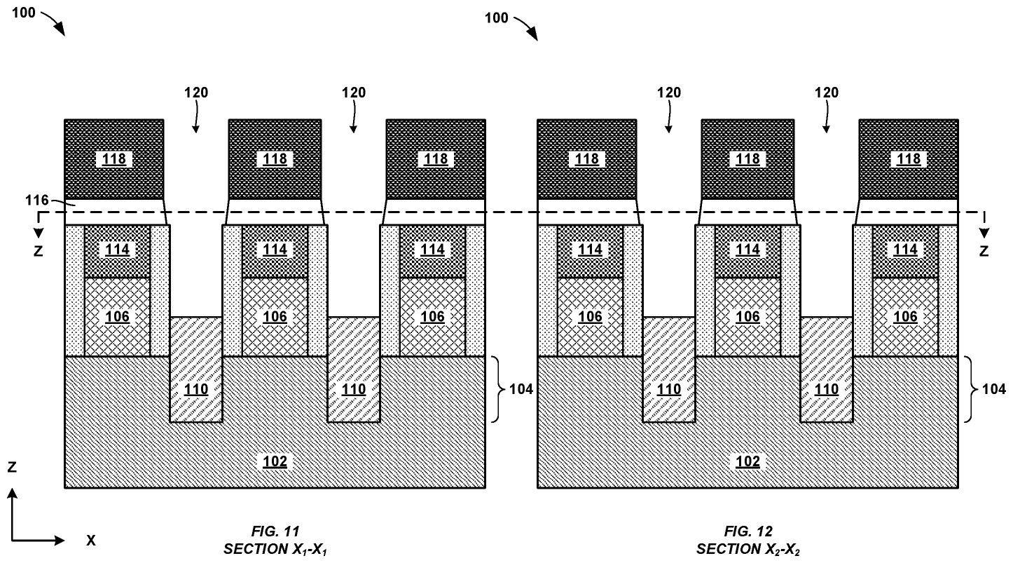

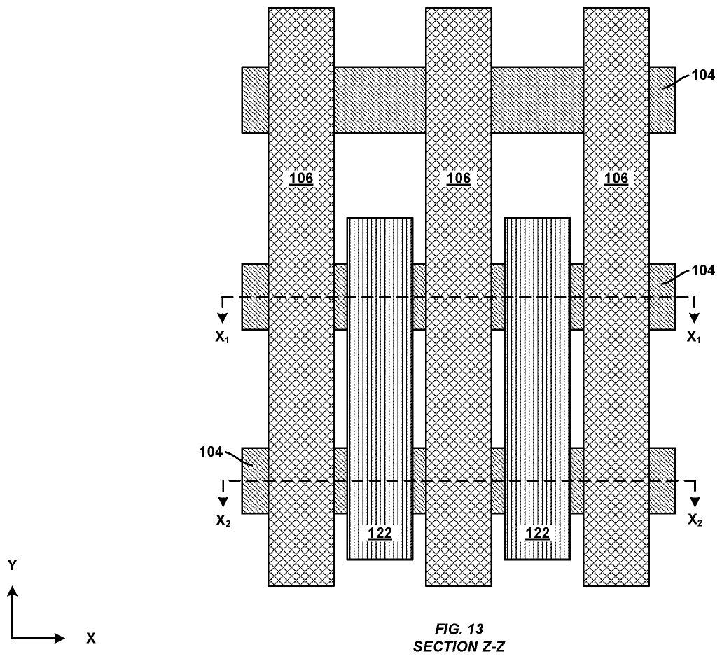

Referring now to FIGS. 10, 11, and 12, a structure 100 is shown after forming source drain contact masks 118 and forming source drain contact trenches 120 according to an embodiment of the invention. FIG. 11 is a representative illustration of a cross-sectional view of the structure 100 shown in FIGS. 12 and 13 taken along line Z-Z and omitting some materials and layers, for example, patterning layers, masking layers and interlevel dielectrics. As such, only pertinent conductive layers and components are shown to provide a clear understanding of their relative orientation. FIG. 12 depicts a cross-sectional view of the structure 100 shown in FIG. 10 taken along line X₁-X₁. FIG. 13 depicts a cross-sectional view of the structure 100 shown in FIG. 10 taken along line X₂-X₂.

First, a first masking material is deposited and subsequently patterned across the structure 100 according to known techniques. After depositing the first masking material, a dry etching technique is applied to pattern the first masking material into the source drain contact masks 118. After forming the source drain contact masks 118, portions of the first MOL dielectric 116 directly above portions of the source drain regions 110 are exposed.

According to an embodiment, the first masking material can be an organic planarization layer (OPL) or a layer of material that is capable of being planarized, etched, or patterned by known techniques. In an embodiment, for example, the first masking material, and thus the source drain contact masks 118, can be an amorphous carbon layer able to withstand subsequent processing temperatures. The source drain contact masks 118 can preferably have a thickness sufficient to cover and protect existing structures during subsequent processing. Although general alignment of the source drain contact masks 118 is important, there is some room for misalignment provided by the gate spacers 108.

Next, portions of the first MOL dielectric 116 and the fill dielectric 112 are selectively etched, or removed, to form the source drain contact trenches 120 according to known techniques. Etching continues until uppermost surfaces of the source drain regions 110 are exposed. Specifically, portions of the first MOL dielectric 116 and the fill dielectric 112 are removed selective to the gate spacers 108 and the source drain regions 110. In at least an embodiment, a directional dry etch technique, such as reactive ion etching, is used to selectively remove portions of the first MOL dielectric 116 and the fill dielectric 112, as shown. Such techniques are commonly referred to as being “self-aligned” because the gate spacers 108 form at least two boundaries of the resulting source drain contact trenches 120. As such, the source drain contact trenches 120 may also be referred to as self-aligned contact trenches.

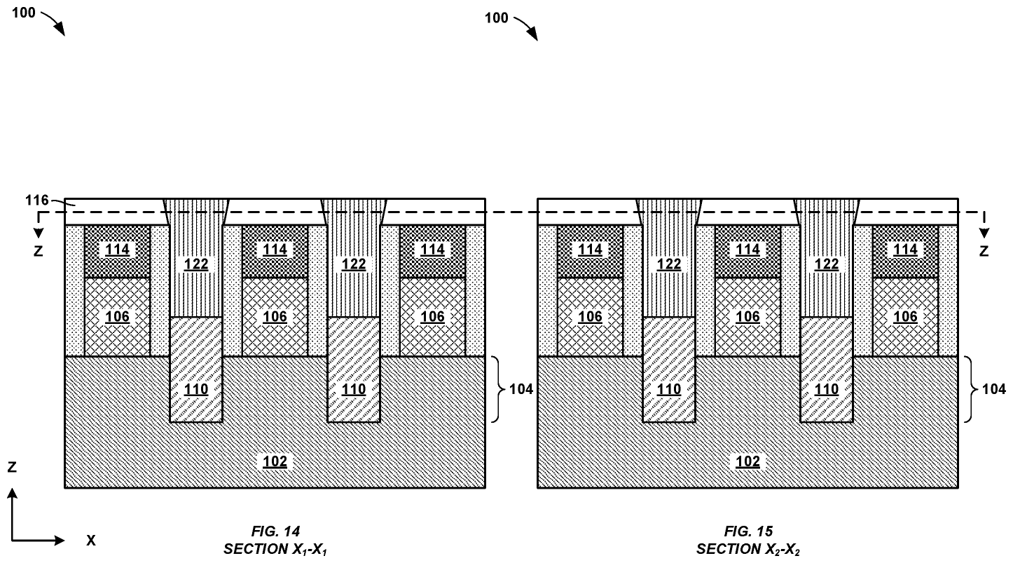

Referring now to FIGS. 13, 14, and 15, a structure 100 is shown after removing the source drain contact masks 118 and forming self-aligned source drain contacts 122 (hereinafter source drain contacts 122) according to an embodiment of the invention. FIG. 13 is a representative illustration of a cross-sectional view of the structure 100 shown in FIGS. 14 and 15 taken along line Z-Z and omitting some materials and layers, for example, patterning layers, masking layers and interlevel dielectrics. As such, only pertinent conductive layers and components are shown to provide a clear understanding of their relative orientation. FIG. 14 depicts a cross-sectional view of the structure 100 shown in FIG. 13 taken along line X₁-X₁. FIG. 15 depicts a cross-sectional view of the structure 100 shown in FIG. 13 taken along line X₂-X₂.

First, the source drain contact masks 118 are removed using known techniques, for example, by ashing. Next, the source drain contact trenches 120 are all filled with a conducive material to form the source drain contacts 122. The source drain contacts 122 may alternatively be referred to as, or labeled as, CA or CA contacts.

The source drain contacts 122 may include any suitable conductive material, such as, for example, copper, ruthenium, aluminum, tungsten, cobalt, or alloys thereof. In some embodiments, a metal silicide is formed at the bottom of the contact trenches prior to filling them with the conductive material. After, excess conductive material can be polished using known techniques until a topmost surface of the source drain contacts 122 are flush, or substantially flush, with topmost surfaces of the gate spacers 108 and the gate caps 114.

Finally, a chemical mechanical polishing technique is used to remove excess unwanted conductive material from upper surfaces of the structure 100. As a result, topmost surfaces of the source drain contacts 122 will be flush, or substantially flush with topmost surfaces of the first MOL dielectric 116.

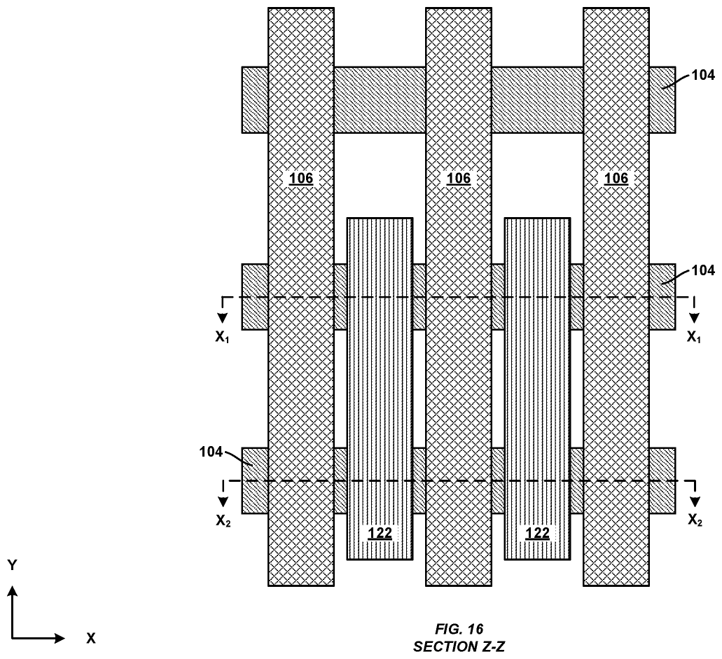

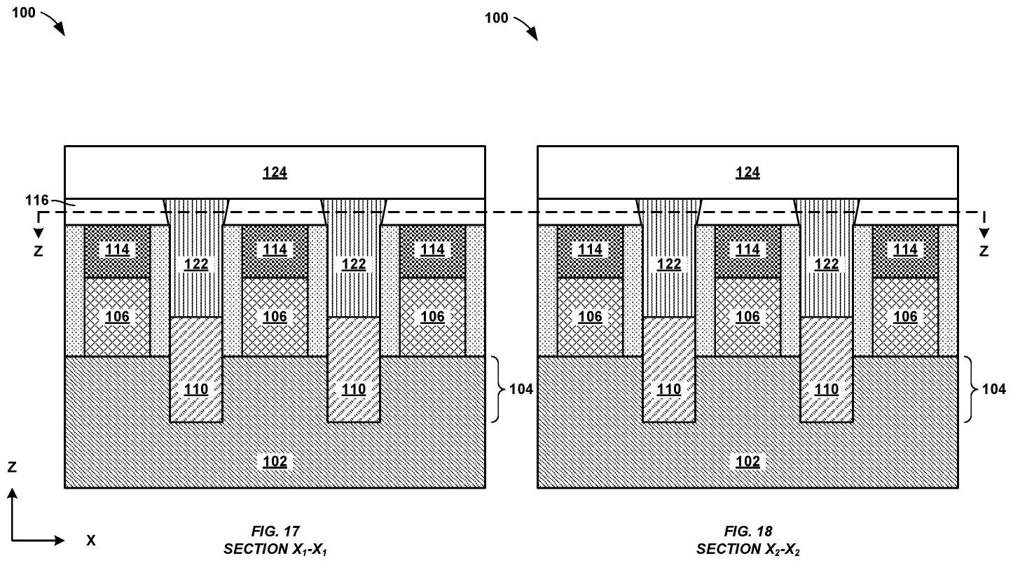

Referring now to FIGS. 16, 17, and 18, a structure 100 is shown after forming a second middle-of-line dielectric layer 124 (hereinafter second MOL dielectric 124) according to an embodiment of the invention. FIG. 16 is a representative illustration of a cross-sectional view of the structure 100 shown in FIGS. 17 and 18 taken along line Z-Z and omitting some materials and layers, for example, patterning layers, masking layers and interlevel dielectrics. As such, only pertinent conductive layers and components are shown to provide a clear understanding of their relative orientation. FIG. 17 depicts a cross-sectional view of the structure 100 shown in FIG. 16 taken along line X₁-X₁. FIG. 18 depicts a cross-sectional view of the structure 100 shown in FIG. 16 taken along line X₂-X₂.

The second MOL dielectric 124 of the present embodiment is blanket deposited across the structure 100 as illustrated and according to known techniques. The second MOL dielectric 124 may include any suitable dielectric material, for example, oxide, nitride, silicon oxide (SiO₂), silicon nitride (Si₃N₄), hydrogenated silicon carbon oxide (SiCOH), carbon rich silicon carbon nitride (SiCN), silicon based low-K dielectrics, porous dielectrics, or some combination thereof.

The second MOL dielectric 124 can be formed using a deposition technique including, for example, chemical vapor deposition (CVD), plasma enhanced chemical vapor deposition (PECVD), physical vapor deposition (PVD), atomic layer deposition (ALD), evaporation, spin-on coating, or sputtering. For example, in an embodiment, the second MOL dielectric 124 is made from hydrogenated silicon carbon oxide (SiCOH). According to at least one embodiment, the second MOL dielectric 124 is made from an identical dielectric material as the first MOL dielectric 116. In at least another embodiment, the second MOL dielectric 124 is made from a different material than the first MOL dielectric 116.

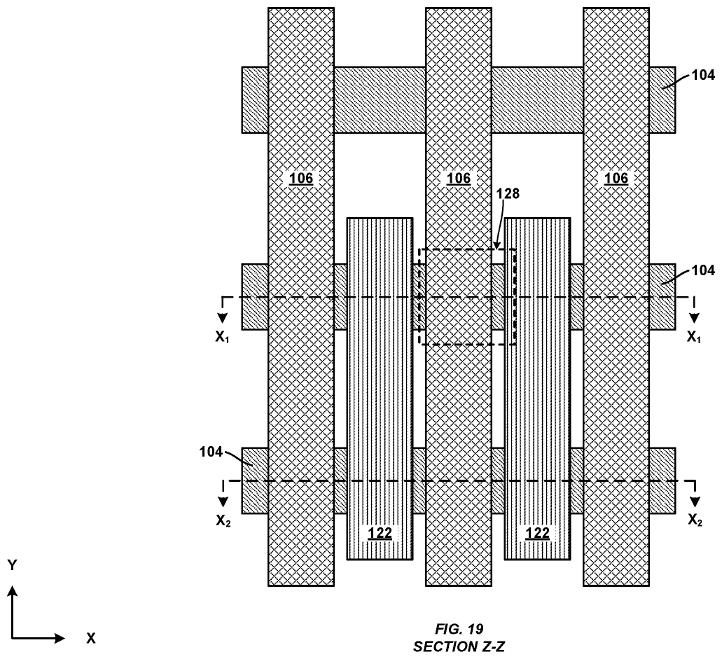

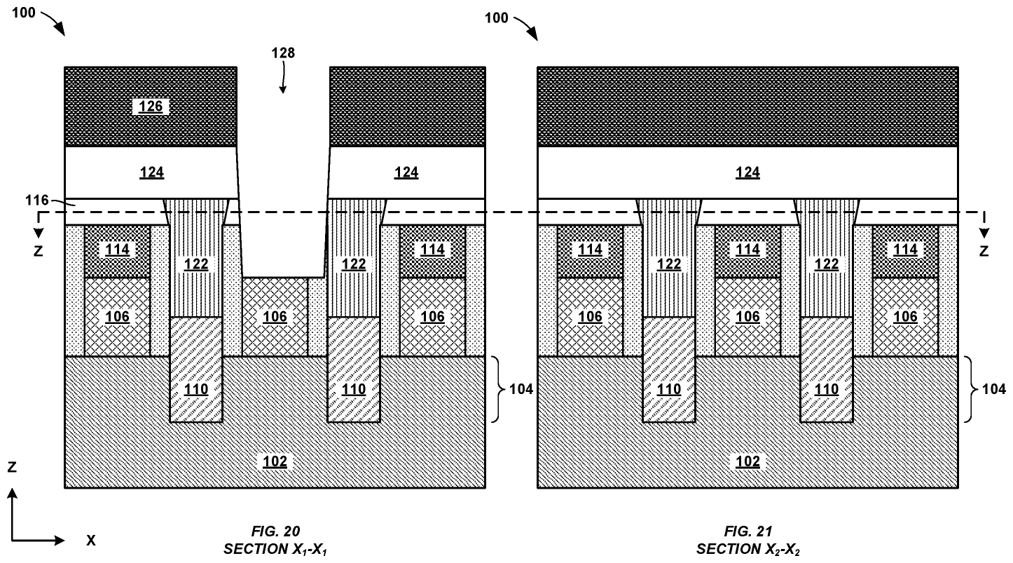

Referring now to FIGS. 19, 20, and 21, a structure 100 is shown after forming gate contact masks 126 and forming gate contact trenches 128 according to an embodiment of the invention. FIG. 19 is a representative illustration of a cross-sectional view of the structure 100 shown in FIGS. 20 and 21 taken along line Z-Z and omitting some materials and layers, for example, patterning layers, masking layers and interlevel dielectrics. As such, only pertinent conductive layers and components are shown to provide a clear understanding of their relative orientation. FIG. 20 depicts a cross-sectional view of the structure 100 shown in FIG. 19 taken along line X₁-X₁. FIG. 21 depicts a cross-sectional view of the structure 100 shown in FIG. 19 taken along line X₂-X₂.

First, a second masking material is deposited and subsequently patterned across the structure 100 according to known techniques. After depositing the second masking material, a dry etching technique is applied to pattern the second masking material into the gate contact masks 126.

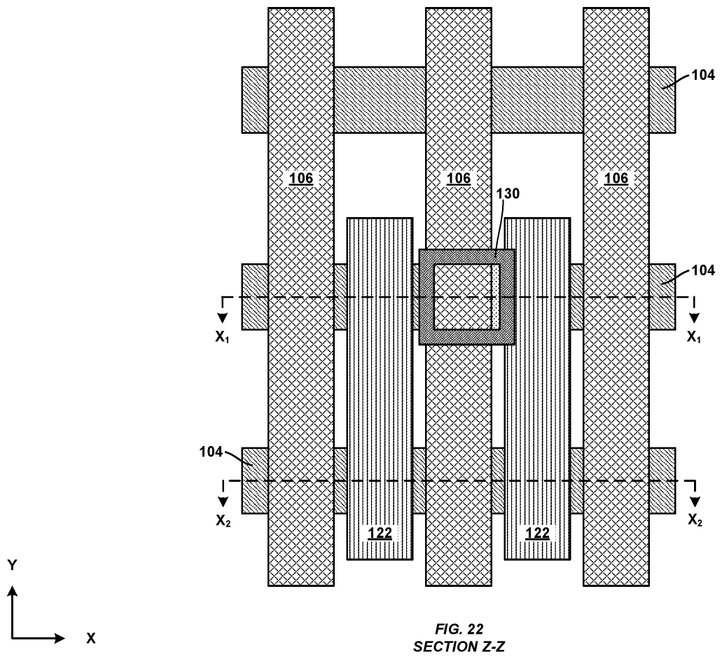

According to an embodiment, the second masking material can be an organic planarization layer (OPL) or a layer of material that is capable of being planarized, etched, or patterned by known techniques. In an embodiment, for example, the second masking material, and thus the gate contact masks 126, can be an amorphous carbon layer able to withstand subsequent processing temperatures. The gate contact masks 126 can preferably have a thickness sufficient to cover and protect existing structures during subsequent processing. Although general alignment of the gate contact masks 126 is important, there is some room for misalignment provided by a subsequently formed isolation layer, as described below with respect to FIGS. 22-24.

Next, portions of the second MOL dielectric 124, the first MOL dielectric 116, and the gate caps 114 are selectively etched, or removed, to form the gate contact trenches 128 according to known techniques. Etching continues until uppermost surfaces of the gates 106 are exposed. Specifically, portions of the second MOL dielectric 124, the first MOL dielectric 116, and the gate caps 114 are removed selective to only the gate contact masks 126. In at least an embodiment, a directional dry etch technique, such as reactive ion etching, is used to selectively remove portions of the second MOL dielectric 124, the first MOL dielectric 116, and the gate caps 114, as shown. Unlike formation of the source drain contact trenches 120, the gate contact trenches 128 are not “self-aligned”. Furthermore, as illustrated in FIG. 20, portions of the gate spacers 108 and the source drain contacts 122 may be also removed, or etched, during forming of the gate contact trenches 128. Exposing the source drain contacts 122 during gate contact formation is typically very undesirable; however, embodiments of the present invention provide a subsequently formed isolation layer used to electrically isolate the source drain contacts 122 from a subsequently formed gate contact, as described below with respect to FIGS. 22-24.

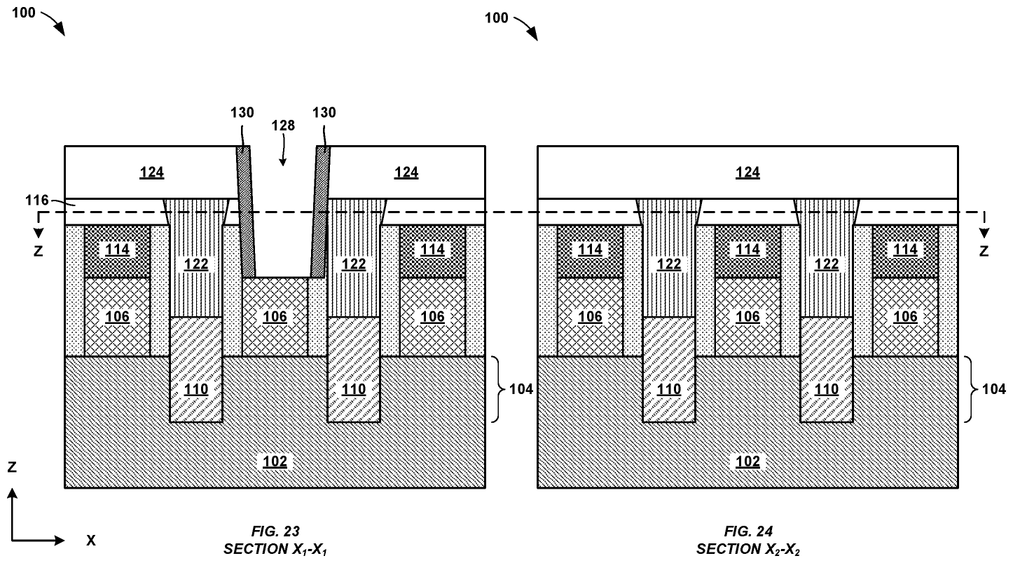

Referring now to FIGS. 22, 23, and 24, a structure 100 is shown after removing the gate contact masks 126 and forming spacers 130 according to an embodiment of the invention. FIG. 22 is a representative illustration of a cross-sectional view of the structure 100 shown in FIGS. 23 and 24 taken along line Z-Z and omitting some materials and layers, for example, patterning layers, masking layers and interlevel dielectrics. As such, only pertinent conductive layers and components are shown to provide a clear understanding of their relative orientation. FIG. 23 depicts a cross-sectional view of the structure 100 shown in FIG. 22 taken along line X₁-X₁. FIG. 24 depicts a cross-sectional view of the structure 100 shown in FIG. 22 taken along line X₂-X₂.

The spacers 130 must be formed along sidewalls of the gate contact trenches 128. The spacers 130 are critical to provide electrical insulation between subsequently formed contact structures, for example a gate contact, and the source drain contacts 122. As a recap, portions, or sidewalls, of the source drain contacts 122 were exposed during forming of the gate contact trenches 128. For example, forming contract structures directly in the gate contact trenches 128 without the spacers 130 would result in direct contact, and thus a short, between the source drain contacts 122 and a subsequently formed gate contact.

In a typical fashion, the spacers 130 are deposited in a conformal manner followed by a directional etching technique to remove portions of the spacers 130 and expose the gates 106, as illustrated in FIG. 23. The spacers 130 should be deposited with a thickness sufficient to ensure the necessary electrical isolation. The final thickness of the spacers 130 should also be limited in an effort to maximize the contact area and reduce contact resistance. According to an embodiment, the spacers 130 can have a lateral thickness ranging from about 4 nm to about 7 nm. The spacers 130 may include any suitable dielectric material, for example, oxide, nitride, silicon oxide (SiO₂), silicon nitride (Si₃N₄), hydrogenated silicon carbon oxide (SiCOH), carbon rich silicon carbon nitride (SiCN), silicon based low-K dielectrics, porous dielectrics, or some combination thereof. For example, in at least an embodiment, the spacers 130 are made from silicon based low-K dielectrics having a dielectric constant less than 4, such as, SiOC. In all cases, the spacers 130 are made from a different material than the gate spacers 108 in order to prevent the possibility of etching, or degradation of, the gate spacers 108 when applying the directional etch to remove portions of the spacers 130 from horizontal surfaces. For example, depending on the alignment, or misalignment, of the gate contact trenches 128 and the lateral thickness of the spacers 130, a relatively small portion of the gate spacers 108 may be exposed at the bottom of the gate contact trenches 128.

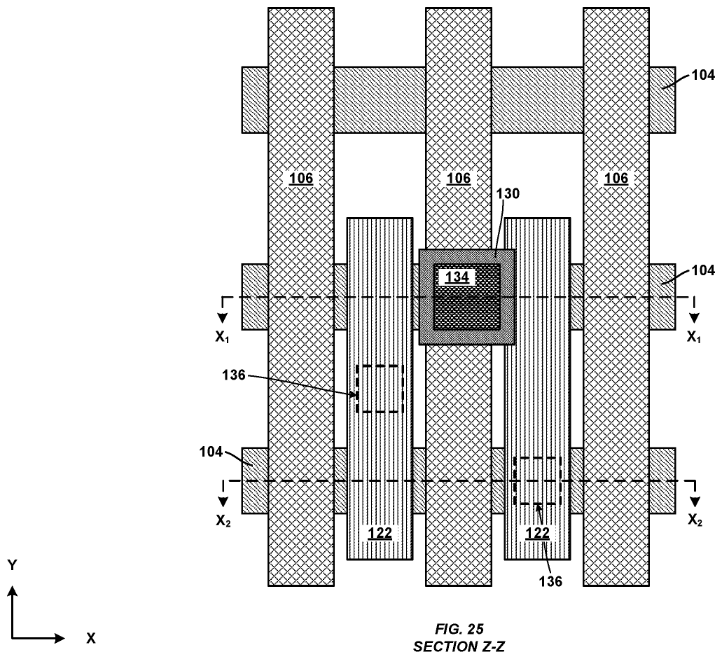

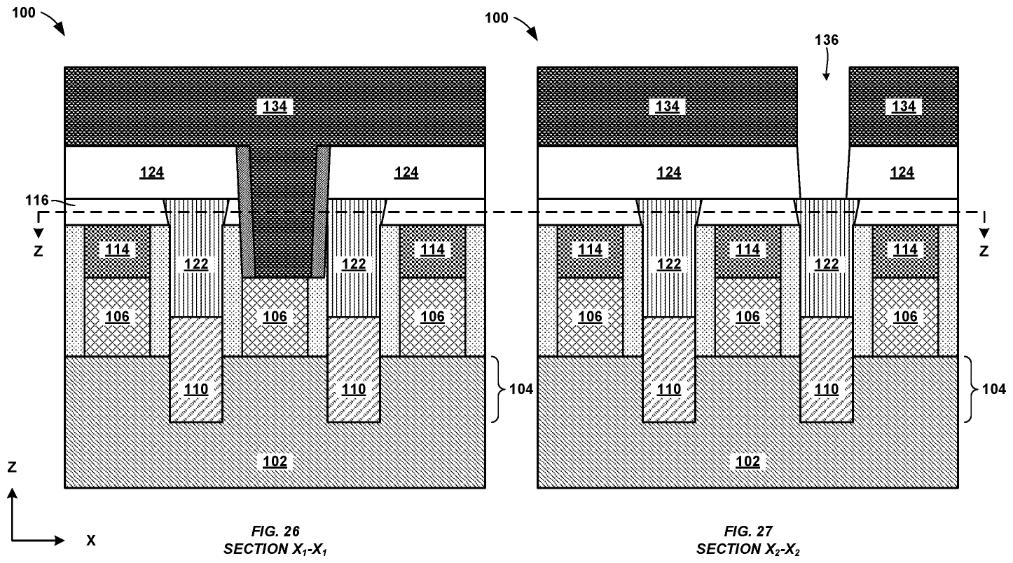

Referring now to FIGS. 25, 26, and 27, a structure 100 is shown after forming via masks 134 and forming via trenches 136 according to an embodiment of the invention. FIG. 25 is a representative illustration of a cross-sectional view of the structure 100 shown in FIGS. 26 and 27 taken along line Z-Z and omitting some materials and layers, for example, patterning layers, masking layers and interlevel dielectrics. As such, only pertinent conductive layers and components are shown to provide a clear understanding of their relative orientation. FIG. 26 depicts a cross-sectional view of the structure 100 shown in FIG. 25 taken along line X₁-X₁. FIG. 27 depicts a cross-sectional view of the structure 100 shown in FIG. 25 taken along line X₂-X₂.

First, a third masking material is deposited and subsequently patterned across the structure 100 according to known techniques. After depositing the third masking material, a dry etching technique is applied to pattern the third masking material into the via masks 134.

According to an embodiment, the third masking material can be an organic planarization layer (OPL) or a layer of material that is capable of being planarized, etched, or patterned by known techniques. In an embodiment, for example, the third masking material, and thus via masks 134, can be an amorphous carbon layer able to withstand subsequent processing temperatures. The via masks 134 can preferably have a thickness sufficient to cover and protect existing structures during subsequent processing.

Next, portions of the second MOL dielectric 124 are selectively etched, or removed, to form the via trenches 136 according to known techniques. Etching continues until uppermost surfaces of the source drain contacts 122 are exposed. Specifically, portions of the second MOL dielectric 124 are removed selective to only the via masks 134. In at least an embodiment, a directional dry etch technique, such as reactive ion etching, is used to selectively remove portions of the second MOL dielectric 124, as shown. It is noted, the third masking material is deposited within the gate contact trenches 128 and directly protects the spacers 130 during forming of the via trenches 136, as illustrated in FIG. 26.

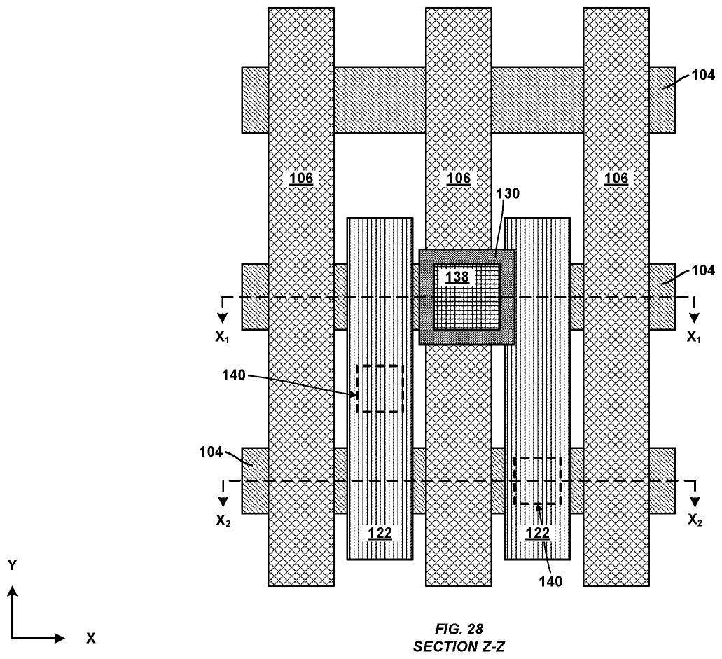

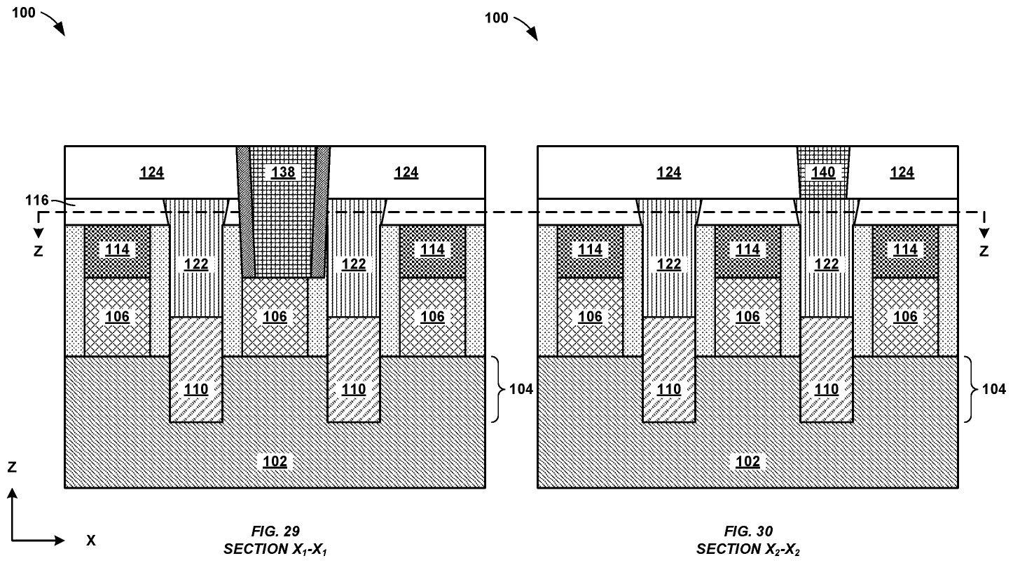

Referring now to FIGS. 28, 29, and 30, a structure 100 is shown after forming gate contacts 138 and vias 140 according to an embodiment of the invention. FIG. 28 is a representative illustration of a cross-sectional view of the structure 100 shown in FIGS. 29 and 30 taken along line Z-Z and omitting some materials and layers, for example, patterning layers, masking layers and interlevel dielectrics. As such, only pertinent conductive layers and components are shown to provide a clear understanding of their relative orientation. FIG. 29 depicts a cross-sectional view of the structure 100 shown in FIG. 28 taken along line X₁-X₁. FIG. 30 depicts a cross-sectional view of the structure 100 shown in FIG. 28 taken along line X₂-X₂.

First, the via masks 134 are removed using known techniques, for example, by ashing. Next, the gate contact trenches 128 and the via trenches 136 are all filled with a conducive material to form the gate contacts 138 and the vias 140, respectively. The gate contacts 138 may alternatively be referred to as, or labeled as, CB or CB contacts.

The gate contacts 138 and the vias 140 may include any suitable conductive material, such as, for example, copper, ruthenium, aluminum, tungsten, cobalt, or alloys thereof. In a preferred embodiment, the gate contacts 138 and the vias 140 are formed without a liner to maximize conductor volume and reduce contact resistance. In some embodiments, a thin conformal metal adhesion liner such as TiN is deposited prior to filling them with the conductive metals. After, excess conductive material can be polished using known techniques until a topmost surface of the gate contacts 138 and the vias 140 are flush, or substantially flush, with topmost surfaces of the second MOL dielectric 124.

Finally, a chemical mechanical polishing technique is used to remove excess unwanted conductive material from upper surfaces of the structure 100. As a result, topmost surfaces of the gate contacts 138 and the vias 140 will be flush, or substantially flush with topmost surfaces of the second MOL dielectric 124.

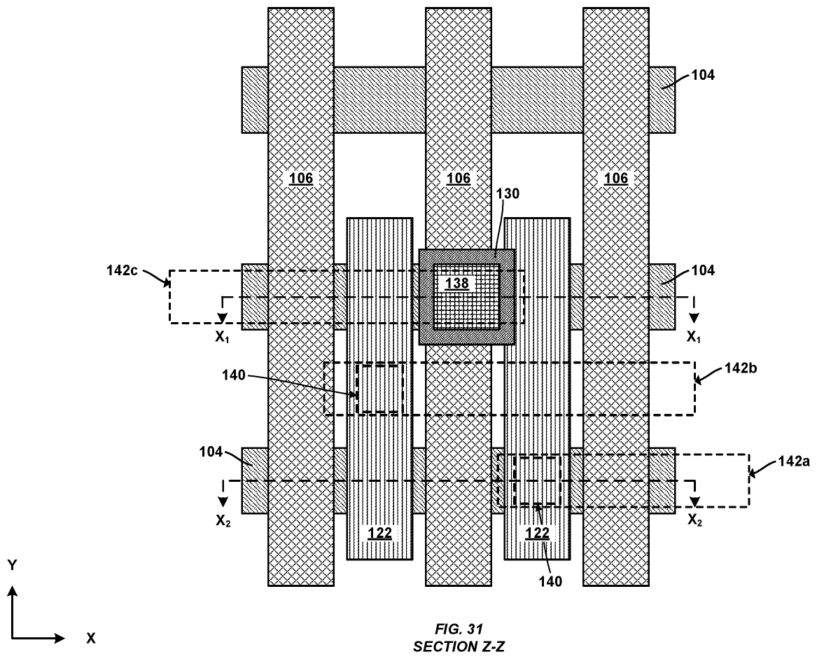

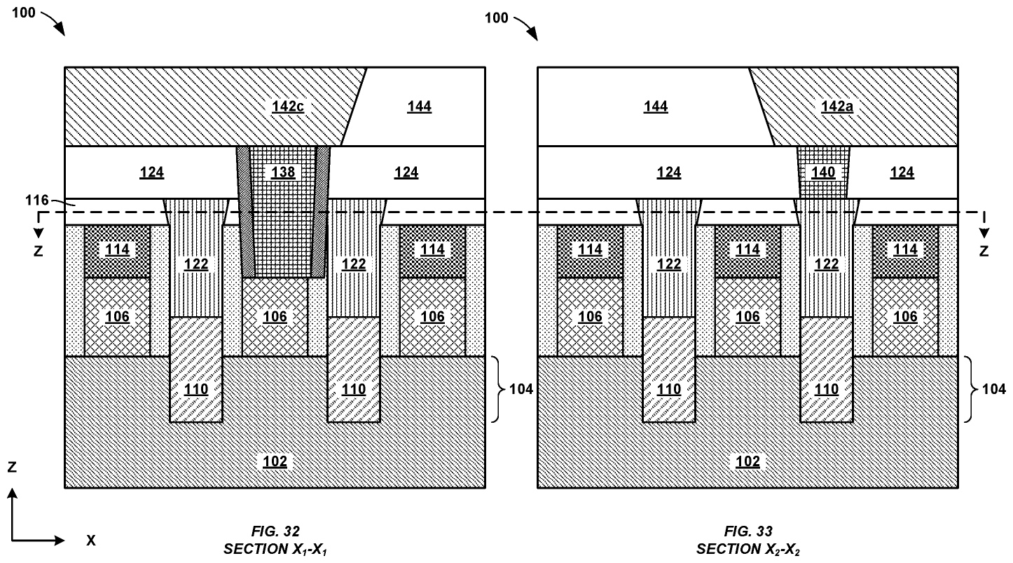

Referring now to FIGS. 31, 32, and 33, a structure 100 is shown after forming a back-end-of-line metallization level including metal lines 142a-c and back-end-of-line dielectric layer 144 (hereinafter BEOL dielectric 144) according to an embodiment of the invention. FIG. 31 is a representative illustration of a cross-sectional view of the structure 100 shown in FIGS. 32 and 33 taken along line Z-Z and omitting some materials and layers, for example, patterning layers, masking layers and interlevel dielectrics. As such, only pertinent conductive layers and components are shown to provide a clear understanding of their relative orientation. FIG. 32 depicts a cross-sectional view of the structure 100 shown in FIG. 31 taken along line X₁-X₁. FIG. 33 depicts a cross-sectional view of the structure 100 shown in FIG. 31 taken along line X₂-X₂.

The metal lines 142a-c of the present embodiment are formed within trenches in the BEOL dielectric 144 as illustrated and according to known techniques. Despite only a single metal line being depicted in FIGS. 32 and 33, embodiments of the present invention explicitly contemplate forming multiple metal lines, as shown in FIG. 33.

The metal lines 142a-c can include any suitable interconnect metal which may be easily deposited within a single damascene trench. For example, the metal lines 142 can include aluminum, copper, ruthenium, cobalt, rhodium, iridium, nickel, or alloys thereof or the like as desired for the application. In at least one embodiment, the metal lines 142 are made from copper. The metal lines 142 can be deposited using known techniques, such as, for example, CVD, sputtering, electrochemical deposition or like processes.

In general, one metal line (142a) forms an electrical connection to one or more source drain contact (122) by way of one or more vias (140), and another metal line (142c) forms an electrical connection to one or more gate contact (138) directly.

In sum, for purposes of this description the structure 100 illustrated in the figures and described herein includes multiple FIN transistor structures; however, the description in its entirety applies equally to other device configurations, such as, for example, ETSOI, nanosheet, stacked FET, nanowire, 2D FET. Embodiments of the present invention, and the detailed description provide above, are directed primarily at the formation of various contact middle-of-line contact structures, for example, the self-aligned source drain contacts 122 and the gate contacts 138.

As illustrated in FIGS. 31-33, the transistor structures represented by the structure 100 have some distinctive notable features. Unlike conventional structures, the self-aligned source drain contacts 122 of the structure 100 are self-aligned and do not extend over or contact any individual self-aligned gate cap 114. Furthermore, as illustrated in the figures, at least a portion of the gate contact 134 is directly above an active region. Said differently, at least a portion of the gate contact 134 is directly above the source drain region 110 or the fin 104 (otherwise channel). Such configurations where the gate contact is over an active region are commonly referred to as CBoA.

With continued reference to FIGS. 31-33, and according to an embodiment, the structure 100 includes a gate with a dielectric gate cap, a self-aligned source drain contact, where a topmost surface of the self-aligned source drain contact is substantially flush with a topmost surface of a first dielectric layer, a gate contact extending through the first dielectric layer, where a topmost surface of the gate contact is substantially flush with a topmost surface of a second dielectric layer, and a spacer surrounding the gate contact and physically separating it from the self-aligned source drain contact.

With continued reference to FIGS. 31-33, and according to an embodiment, the structure 100 includes a gate with a dielectric gate cap, a self-aligned source drain contact, where a topmost surface of the self-aligned source drain contact is substantially flush with a topmost surface of a first dielectric layer, a gate contact extending through the first dielectric layer, where a topmost surface of the gate contact is substantially flush with a topmost surface of a second dielectric layer, a spacer surrounding the gate contact and physically separating it from the self-aligned source drain contact, and gate spacers physically separating the gate from source drain regions, where the spacers directly contact the dielectric gate cap and the spacer.

With continued reference to FIGS. 31-33, and according to an embodiment, the structure 100 includes a gate with a dielectric gate cap, a first dielectric layer, a self-aligned source drain contact extending through the first dielectric layer, a second dielectric layer above the first dielectric layer, a gate contact extending through both the first dielectric layer the second dielectric layer, and a sidewall spacer surrounding the gate contact and physically separating it from the self-aligned source drain contact.

With continued reference to FIGS. 31-33, and according to an embodiment, the structure 100 further includes a via above and contacting the self-aligned source drain contact, where a topmost surface of the via is substantially flush with the topmost surface of the second dielectric layer.

With continued reference to FIGS. 31-33, and according to an embodiment, the structure 100 further includes a back-end-of-line metallization level comprising metal wires, where the metal wires directly contact top surfaces of both the self-aligned source drain contact and the gate contact.

With continued reference to FIGS. 31-33, and according to an embodiment, a bottommost surface of the gate contact is below the topmost surface of the self-aligned source drain contact.

With continued reference to FIGS. 31-33, and according to an embodiment, where the spacer comprises a high-k dielectric material having a dielectric constant less than 4.

With continued reference to FIGS. 31-33, and according to an embodiment, the spacer comprises SiOC.

With continued reference to FIGS. 31-33, and according to an embodiment, at least a portion of the gate contact is directly above an active region.

What is claimed is:

1. A transistor structure comprising:
a gate with a dielectric gate cap;
a self-aligned source drain contact, wherein a topmost surface of the self-aligned source drain contact is substantially flush with a topmost surface of a first dielectric layer;
a gate contact extending through the first dielectric layer, wherein a topmost surface of the gate contact is substantially flush with a topmost surface of a second dielectric layer; and
a spacer surrounding the gate contact and physically separating it from the self-aligned source drain contact.

2. The transistor structure according to claim 1, further comprising:
a via above and contacting the self-aligned source drain contact, wherein a topmost surface of the via is substantially flush with the topmost surface of the second dielectric layer.

3. The transistor structure according to claim 1, further comprising:
a back-end-of-line metallization level comprising metal wires, wherein the metal wires directly contact top surfaces of both the self-aligned source drain contact and the gate contact.

4. The transistor structure according to claim 1, wherein a bottommost surface of the gate contact is below the topmost surface of the self-aligned source drain contact.

5. The transistor structure according to claim 1, wherein the spacer comprises a high-k dielectric material having a dielectric constant less than 4.

6. The transistor structure according to claim 1, wherein the spacer comprises SiOC.

7. The transistor structure according to claim 1, wherein at least a portion of the gate contact is directly above an active region.

8. A transistor structure comprising:
a gate with a dielectric gate cap;
a self-aligned source drain contact, wherein a topmost surface of the self-aligned source drain contact is substantially flush with a topmost surface of a first dielectric layer;
a gate contact extending through the first dielectric layer, wherein a topmost surface of the gate contact is substantially flush with a topmost surface of a second dielectric layer;
a spacer surrounding the gate contact and physically separating it from the self-aligned source drain contact; and
gate spacers physically separating the gate from source drain regions, wherein the spacers directly contact the dielectric gate cap and the spacer.

9. The transistor structure according to claim 1, further comprising:
a via above and contacting the self-aligned source drain contact, wherein a topmost surface of the via is substantially flush with the topmost surface of the second dielectric layer.

10. The transistor structure according to claim 8, further comprising:
a back-end-of-line metallization level comprising metal wires, wherein the metal wires directly contact top surfaces of both the self-aligned source drain contact and the gate contact.

11. The transistor structure according to claim 8, wherein a bottommost surface of the gate contact is below the topmost surface of the self-aligned source drain contact.

12. The transistor structure according to claim 8, wherein the spacer comprises a high-k dielectric material having a dielectric constant less than 4.

13. The transistor structure according to claim 8, wherein the spacer comprises SiOC.

14. A transistor structure comprising:
a gate with a dielectric gate cap;
a first dielectric layer;
a self-aligned source drain contact extending through the first dielectric layer;
a second dielectric layer above the first dielectric layer;
a gate contact extending through both the first dielectric layer the second dielectric layer; and
a sidewall spacer surrounding the gate contact and physically separating it from the self-aligned source drain contact.

15. The transistor structure according to claim 1, further comprising:
a via above and contacting the self-aligned source drain contact, wherein a topmost surface of the via is substantially flush with the topmost surface of the second dielectric layer.

16. The transistor structure according to claim 14, further comprising:
a back-end-of-line metallization level comprising metal wires, wherein the metal wires directly contact top surfaces of both the self-aligned source drain contact and the gate contact.

17. The transistor structure according to claim 14, wherein a bottommost surface of the gate contact is below a topmost surface of the self-aligned source drain contact.

18. The transistor structure according to claim 14, wherein the spacer comprises a high-k dielectric material having a dielectric constant less than 4.

19. The transistor structure according to claim 14, wherein the spacer comprises SiOC.

20. The transistor structure according to claim 14, wherein at least a portion of the gate contact is directly above an active region.
